(19) United States
(12) Patent Application Publication
(10) Pub. No.: US 2023/0152045 A1
(43) Pub. Date: May 18, 2023

(54) LIQUID COOLING HEAT DISSIPATION SUBSTRATE WITH PARTIAL COMPRESSION REINFORCEMENT

(71) Applicant: AMULAIRE THERMAL TECHNOLOGY, INC., New Taipei City (TW)

(72) Inventors: CHENG-SHU PENG, New Taipei City (TW); YEN-CHUN LIN, New Taipei City (TW); TZE-YANG YEH, New Taipei City (TW)

(21) Appl. No.: 17/527,097

(22) Filed: Nov. 15, 2021

(51) Int. Cl. F28F 3/02

(52) U.S. Cl. CPC F28F 3/02; F28F 2225/06; F28F 2215/10

(57) ABSTRACT

A liquid cooling heat dissipation substrate with partial compression reinforcement is provided. The liquid cooling heat dissipation substrate with partial compression reinforcement includes a heat dissipation base and a compression reinforcement structure. The heat dissipation base integrally has an upper surface and a lower surface opposite to each other, and the compression reinforcement structure is partially formed on at least one of the upper surface and the lower surface. A ratio of a sum of an area of an orthogonal projection of the compression reinforcement structure on the upper surface and an area of an orthogonal projection of the compression reinforcement structure on the lower surface to a sum of an area of the upper surface and an area of the lower surface is from 10% to 60%.

### FIELD OF THE DISCLOSURE

The present disclosure relates to a heat dissipation substrate, and more particularly to a liquid cooling heat dissipation substrate with partial compression reinforcement.

### BACKGROUND OF THE DISCLOSURE

Due to the heat dissipation requirements of high-power heating elements, conventionally, main bodies of heat sinks of the high-power heating elements are mostly made of copper. However, regardless of whether the heat sink is formed by metal diffusion bonding or metal sintering, the material strength thereof is inevitably decreased, thereby leading to a significant decrease in service life of the product.

### SUMMARY OF THE DISCLOSURE

In response to the above-referenced technical inadequacies, the present disclosure provides a liquid cooling heat dissipation substrate with partial compression reinforcement.

In one aspect, the present disclosure provides a liquid cooling heat dissipation substrate with partial compression reinforcement that includes a heat dissipation base and a compression reinforcement structure. The heat dissipation base integrally has an upper surface and a lower surface that are opposite to each other, and the compression reinforcement structure is partially formed on at least one of the upper surface and the lower surface. A ratio of a sum of an area of an orthogonal projection of the compression reinforcement structure on the upper surface and an area of an orthogonal projection of the compression reinforcement structure on the lower surface to a sum of an area of the upper surface and an area of the lower surface is from 10% to 60%.

In an exemplary embodiment, the heat dissipation base is an integral structure formed through a metal diffusion bonding process, and the compression reinforcement structure is formed by performing compression reinforcement on portions of the heat dissipation base through a pressure application process.

In an exemplary embodiment, the heat dissipation base is an integral structure formed through a metal powder sintering process, and the compression reinforcement structure is formed by performing compression reinforcement on portions of the heat dissipation base through a pressure application process.

In an exemplary embodiment, the heat dissipation base is formed from one of copper and a copper alloy.

In an exemplary embodiment, a fin structure is integrally formed on the upper surface of the heat dissipation base, and a plurality of reinforcement portions of the compression reinforcement structure and a plurality of fins of the fin structure are arranged alternately and in parallel to each other.

In an exemplary embodiment, a fin structure is integrally formed on the upper surface of the heat dissipation base, and a plurality of reinforcement portions of the compression reinforcement structure are in alternate and parallel arrangement with a plurality of pin-fins of the fin structure that are arranged in rows.

In an exemplary embodiment, a fin structure is integrally formed on the upper surface of the heat dissipation base, and a plurality of reinforcement portions of the compression reinforcement structure are alternately arranged between a plurality of pin-fins of the fin structure in perpendicular and parallel manners.

In an exemplary embodiment, the compression reinforcement structure is at least one of an indentation, a depression, a patterned indentation and a patterned depression.

In an exemplary embodiment, an indentation depth of the compression reinforcement structure is equal to or less than 15% of a thickness of the heat dissipation base.

Therefore, in the liquid cooling heat dissipation substrate with partial compression reinforcement provided by the present disclosure, by virtue of “a heat dissipation base integrally having an upper surface and a lower surface opposite to each other, and a compression reinforcement structure partially formed on at least one of the upper surface and the lower surface,” and “a ratio of a sum of an area of an orthogonal projection of the compression reinforcement structure on the upper surface and an area of an orthogonal projection of the compression reinforcement structure on the lower surface to a sum of an area of the upper surface and an area of the lower surface being from 10% to 60%,” a heat dissipation effect can be maintained, and a structural strength of the liquid cooling heat dissipation substrate can be strengthened.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a liquid cooling heat dissipation substrate with partial compression reinforcement according to a first embodiment of the present disclosure;

FIG. 2 is a schematic side view of a liquid cooling heat dissipation substrate with partial compression reinforcement according to the first embodiment of the present disclosure;

FIG. 3 is a schematic top view of a liquid cooling heat dissipation substrate with partial compression reinforcement according to a second embodiment of the present disclosure;

FIG. 4 is a schematic side view of a liquid cooling heat dissipation substrate with partial compression reinforcement according to the second embodiment of the present disclosure;

FIG. 5 is a schematic top view of a liquid cooling heat dissipation substrate with partial compression reinforcement according to a third embodiment of the present disclosure;

FIG. 6 is a schematic side view of a liquid cooling heat dissipation substrate with partial compression reinforcement according to the third embodiment of the present disclosure;

FIG. 7 is a schematic top view of a liquid cooling heat dissipation substrate with partial compression reinforcement according to a fourth embodiment of the present disclosure; and

FIG. 8 is a schematic side view of a liquid cooling heat dissipation substrate with partial compression reinforcement according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

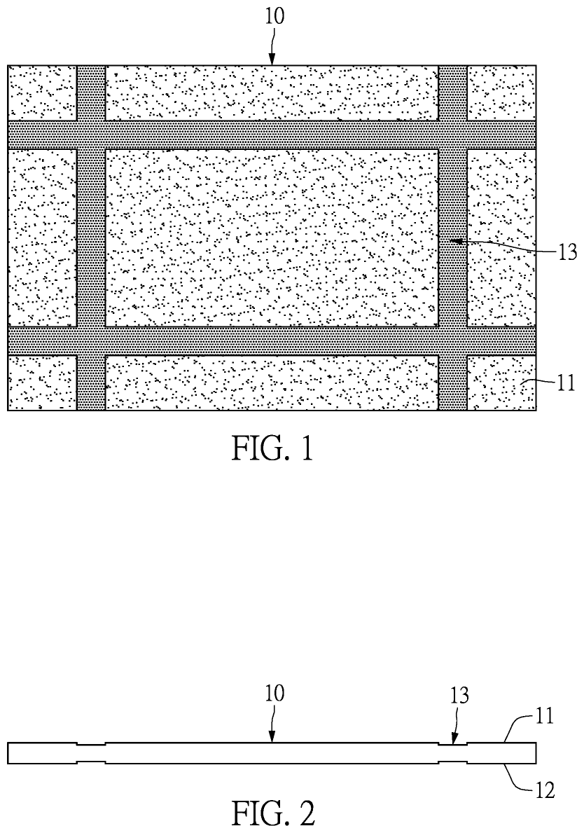

Reference is made to FIG. 1 and FIG. 2, which show an embodiment of the present disclosure. A liquid cooling heat dissipation substrate with partial compression reinforcement is provided in this embodiment of the present disclosure for contacting heat emitting elements. As shown in FIG. 1 and FIG. 2, the liquid cooling heat dissipation substrate with partial compression reinforcement provided in the present disclosure can include a heat dissipation base 10 that integrally has an upper surface 11 and a lower surface 12 and a compression reinforcement structure 13 that is partially formed on at least one of the upper surface 11 and the lower surface 12.

Furthermore, the heat dissipation base 10 of this embodiment is an integral structure formed through a metal diffusion bonding process, and the heat dissipation base 10 can be a liquid cooling porous heat sink being immersed in a two-phase coolant and having a porosity greater than 5%, so as to improve an overall heat dissipation effect. Furthermore, since the heat dissipation base 10 is formed through a metal diffusion bonding process, a structural strength thereof is inevitably reduced. Therefore, in order to maintain a heat dissipation effect and strengthen the structural strength of the heat dissipation base 10, in this embodiment, a ratio of a sum of an area of an orthogonal projection of the compression reinforcement structure 13 on the upper surface 11 and an area of an orthogonal projection of the compression reinforcement structure 13 on the lower surface 12 to a sum of an area of the upper surface 11 and an area of the lower surface 12 is from 10% to 60%, thereby maintaining the heat dissipation effect and strengthening the structural strength.

Specifically, the compression reinforcement structure 13 of this embodiment can be a reinforcement structure formed by performing compression reinforcement on portions of the heat dissipation base 10 through a pressure application process (e.g., a stamping process, a forging process or a press forging process). Furthermore, the compression reinforcement structure 13 can be an indentation, a depression, a patterned indentation, or a patterned depression, and an indentation depth of the compression reinforcement structure 13 is equal to or less than 15% of a thickness of the heat dissipation base 10.

Furthermore, the heat dissipation base 10 of this embodiment can be an integral structure formed through a metal powder sintering process, and can be a liquid-cooling heat sink formed by sintering of copper or a copper alloy powder. Afterwards, the compression reinforcement structure 13 is formed by performing compression reinforcement on portions of the heat dissipation base 10 through a pressure application process.

In addition, in this embodiment, the ratio of the sum of the area of the orthogonal projection of the compression reinforcement structure 13 on the upper surface 11 and the area of the orthogonal projection of the compression reinforcement structure 13 on the lower surface 12 to the sum of the area of the upper surface 11 and the area of the lower surface 12 is substantially 27%.

### Second Embodiment

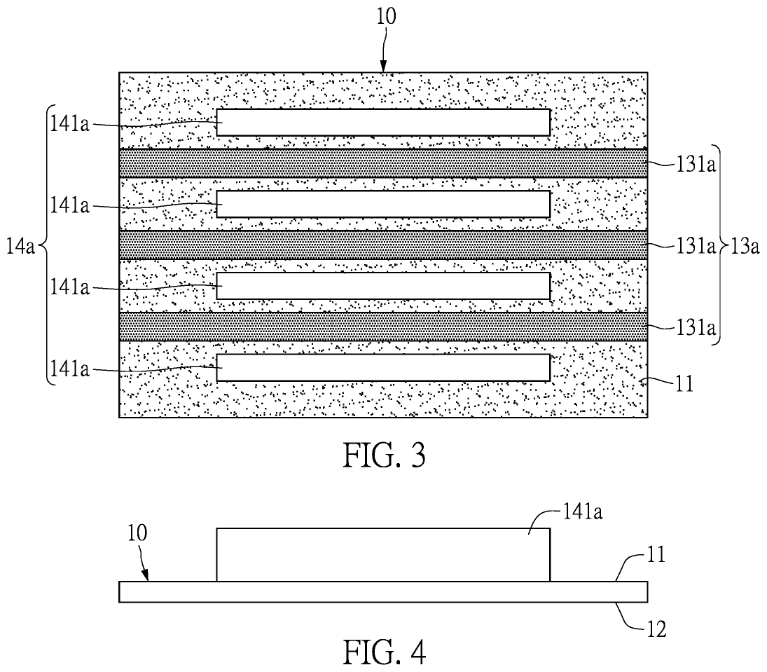

Reference is made to FIG. 3 and FIG. 4, which show a second embodiment of the present disclosure. This embodiment is substantially the same as the first embodiment, and differences therebetween are described as follows.

Specifically, as shown in a schematic top view of FIG. 3, a fin structure 14a is integrally formed on the upper surface 11 of the heat dissipation base 10, and a plurality of reinforcement portions 131a of a compression reinforcement structure 13a and a plurality of plate-shaped fins 141a of the fin structure 14a are arranged alternately and in parallel to each other, effectively increasing the heat dissipation effect and the structural strength of the liquid cooling heat dissipation substrate.

Furthermore, in this embodiment, the ratio of the sum of the area of the orthogonal projection of the compression reinforcement structure 13a on the upper surface 11 and the area of the orthogonal projection of the compression reinforcement structure 13a on the lower surface 12 to the sum of the area of the upper surface 11 and the area of the lower surface 12 is substantially 25%.

### Third Embodiment

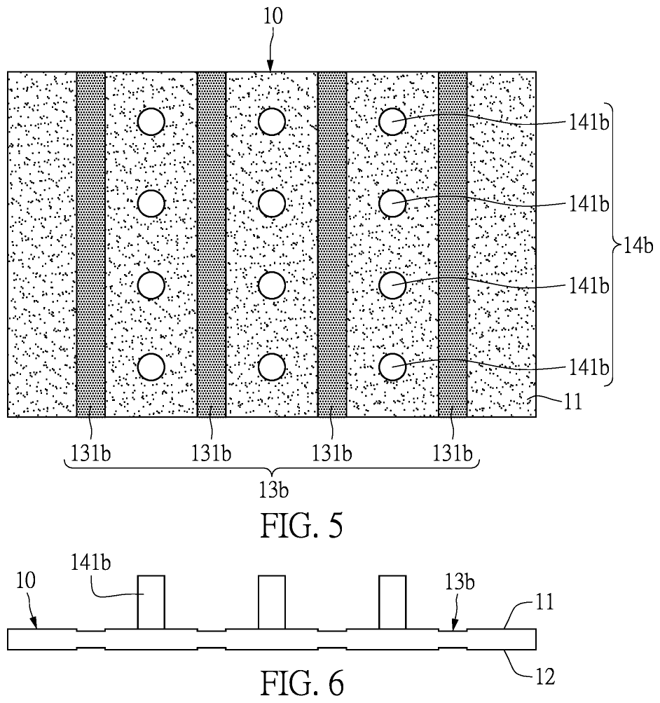

Reference is made to FIG. 5 and FIG. 6, which show a third embodiment of the present disclosure. This embodiment is substantially the same as the first embodiment, and differences therebetween are described as follows.

Specifically, as shown in a schematic top view of FIG. 5, a fin structure 14b is integrally formed on the upper surface 11 of the heat dissipation base 10, and a plurality of reinforcement portions 131b of a compression reinforcement structure 13b are in alternate and parallel arrangement with a plurality of pin-fins 141b of the fin structure 14b that are arranged in rows, effectively increasing the heat dissipation effect and the structural strength of the liquid cooling heat dissipation substrate.

Furthermore, in this embodiment, the ratio of the sum of the area of the orthogonal projection of the compression reinforcement structure 13b on the upper surface 11 and the area of the orthogonal projection of the compression reinforcement structure 13b on the lower surface 12 to the sum of the area of the upper surface 11 and the area of the lower surface 12 is substantially 20%.

### Fourth Embodiment

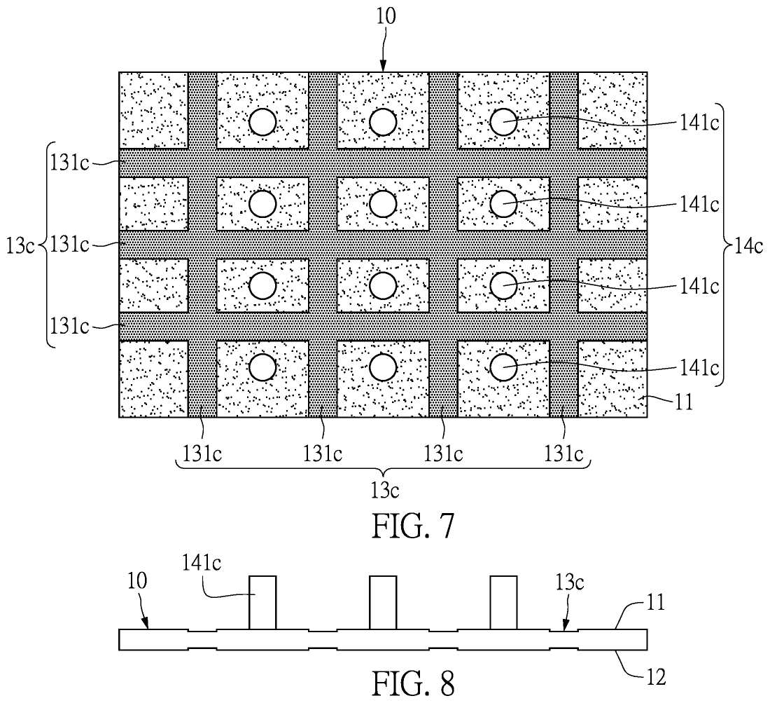

Reference is made to FIG. 7 and FIG. 8, which show a fourth embodiment of the present disclosure. This embodiment is substantially the same as the first embodiment, and differences therebetween are described as follows.

Specifically, as shown in a schematic top view of FIG. 7, a fin structure 14c is integrally formed on the upper surface 11 of the heat dissipation base 10, and a plurality of reinforcement portions 131c of a compression reinforcement structure 13c are alternately arranged between a plurality of pin-fins 141c of the fin structure 14c in perpendicular and parallel manners, effectively increasing the heat dissipation effect and the structural strength of the liquid cooling heat dissipation substrate.

Furthermore, in this embodiment, the ratio of the sum of the area of the orthogonal projection of the compression reinforcement structure 13c on the upper surface 11 and the area of the orthogonal projection of the compression reinforcement structure 13b on the lower surface 12 to the sum of the area of the upper surface 11 and the area of the lower surface 12 is substantially 45%.

### Beneficial Effects of the Embodiments

In conclusion, in the liquid cooling heat dissipation substrate with partial compression reinforcement provided by the present disclosure, by virtue of “a heat dissipation base integrally having an upper surface and a lower surface opposite to each other, and a compression reinforcement structure partially formed on at least one of the upper surface and the lower surface,” and “a ratio of a sum of an area of an orthogonal projection of the compression reinforcement structure on the upper surface and an area of an orthogonal projection of the compression reinforcement structure on the lower surface to a sum of an area of the upper surface and an area of the lower surface being from 10% to 60%,” a heat dissipation effect can be maintained, and a structural strength of the liquid cooling heat dissipation substrate can be strengthened.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid cooling heat dissipation substrate with partial compression reinforcement, comprising:
a heat dissipation base integrally having an upper surface and a lower surface opposite to each other, and a compression reinforcement structure partially formed on at least one of the upper surface and the lower surface; wherein a ratio of a sum of an area of an orthogonal projection of the compression reinforcement structure on the upper surface and an area of an orthogonal projection of the compression reinforcement structure on the lower surface to a sum of an area of the upper surface and an area of the lower surface is from 10% to 60%.

2. The liquid cooling heat dissipation substrate according to claim 1, wherein the heat dissipation base is an integral structure formed through a metal diffusion bonding process, and the compression reinforcement structure is formed by performing compression reinforcement on portions of the heat dissipation base through a pressure application process.

3. The liquid cooling heat dissipation substrate according to claim 1, wherein the heat dissipation base is an integral structure formed through a metal powder sintering process, and the compression reinforcement structure is formed by performing compression reinforcement on portions of the heat dissipation base through a pressure application process.

4. The liquid cooling heat dissipation substrate according to claim 1, wherein the heat dissipation base is formed from one of copper and a copper alloy.

5. The liquid cooling heat dissipation substrate according to claim 1, wherein a fin structure is integrally formed on the upper surface of the heat dissipation base, and a plurality of reinforcement portions of the compression reinforcement structure and a plurality of fins of the fin structure are arranged alternately and in parallel to each other.

6. The liquid cooling heat dissipation substrate according to claim 1, wherein a fin structure is integrally formed on the upper surface of the heat dissipation base, and a plurality of reinforcement portions of the compression reinforcement structure are in alternate and parallel arrangement with a plurality of pin-fins of the fin structure.

7. The liquid cooling heat dissipation substrate according to claim 1, wherein a fin structure is integrally formed on the upper surface of the heat dissipation base, and a plurality of reinforcement portions of the compression reinforcement structure are alternately arranged between a plurality of pin-fins of the fin structure in perpendicular and parallel manners.

8. The liquid cooling heat dissipation substrate according to claim 1, wherein the compression reinforcement structure is at least one of an indentation, a depression, a patterned indentation and a patterned depression.

9. The liquid cooling heat dissipation substrate according to claim 8, wherein an indentation depth of the compression reinforcement structure is equal to or less than 15% of a thickness of the heat dissipation base.
